(19) United States
(12) Patent Application Publication
(10) Pub. No.: US 2025/0019835 A1
(43) Pub. Date: Jan. 16, 2025

(54) ETCHING DEVICE AND ETCHING SYSTEM

(71) Applicants: Cloeren Technology GmbH, Niederkruechten (DE); Steinbeis Transfer GmbH, Stuttgart (DE)

(72) Inventors: Dominik BRITZ, Wallerfangen (DE); Frank MUECKLICH, Schwalbach (DE); Heinz-Hubert CLOEREN, Niederkruechten (DE); Berat BUELBUEL, Erkelenz (DE)

(73) Assignees: Cloeren Technology GmbH, Niederkruechten (DE); Steinbeis Transfer GmbH, Stuttgart (DE)

(21) Appl. No.: 18/815,073

(22) Filed: Aug. 26, 2024

Related U.S. Application Data
(63) Continuation of application No. PCT/EP2023/054397, filed on Feb. 22, 2023.

(30) Foreign Application Priority Data
Feb. 24, 2022 (DE) 10 2022 104 460.2

(51) Int. Cl. C23F 1/08

(52) U.S. Cl. CPC C23F 1/08

(57) ABSTRACT

An etching device for a workpiece to be processed via an etching liquid, the device comprising a cavity into which the workpiece can be introduced. The cavity is surrounded at least in some regions by at least one lock of the etching device for the workpiece. The lock and an end face of the etching device facing the lock partially surround a gap for the introduction of the etching liquid. The end face of the etching device facing the lock is transparent at least in some regions. The invention also relates to an etching system having the etching device, wherein the etching device is connected to at least one etching liquid source via at least one etching liquid supply line and to at least one etching liquid reservoir via at least one etching liquid discharge line.

This nonprovisional application is a continuation of International Application No. PCT/EP2023/054397, which was filed on Feb. 22, 2023, and which claims priority to German Patent Application No. 10 2022 104 460.2, which was filed in Germany on Feb. 24, 2022, and which are both herein incorporated by reference.

### BACKGROUND OF THE INVENTION

### Field of the Invention

The invention relates to an etching device for a workpiece to be processed via an etching liquid and to an etching system having the etching device.

### Description of the Background Art

Etching devices are used for the chemical processing of workpieces. The etching liquid, also called pickling fluid, is applied to a surface to be processed of the workpiece. A chemical reaction takes place between the etching liquid and the workpiece surface, in which the workpiece surface is removed and a depression is formed. In this way, metallic workpieces in particular can be structured in a user-defined manner, or electrical conductor tracks can be formed on printed circuit boards in electronics manufacturing. The workpiece surface can also be contrasted with a heterogeneous structure for material testing. In so-called color etching, different layers of a workpiece surface can be selectively colored.

It is desirable to examine the chemical reaction between the etching liquid and the workpiece surface to be processed as precisely as possible and to control the process thereof in order to achieve a high etching quality.

The known etching devices have the disadvantage that the etching of the workpiece must be optimized empirically, since there is no reliable monitoring of the etching process, in particular in situ, i.e., during the etching process.

### SUMMARY OF THE INVENTION

It is therefore an object of the invention to develop an etching device that allows an optimized etching process in a time- and cost-effective manner while avoiding the disadvantages of the prior art. This applies, mutatis mutandis, to the etching system.

The object of the invention is achieved, in an example, by an etching device for a workpiece to be processed via an etching liquid, the device comprising a cavity into which the workpiece can be introduced, wherein the cavity can be surrounded at least in some regions by at least one lock of the etching device for the workpiece, wherein the lock and an end face of the etching device facing the lock partially surround a gap for the introduction of the etching liquid, and wherein the end face of the etching device facing the lock can be transparent at least in some regions. In addition, the object of the invention is achieved by an etching system having an etching device according to the invention, wherein the etching device is connected to at least one etching liquid source via at least one etching liquid supply line and to at least one etching liquid reservoir via at least one etching liquid discharge line.

The invention is based on the basic idea that, with the lock, there is a stop for the surface to be processed of the workpiece, which stop is simple to provide and reproducible owing to the design. In addition, the surface to be processed of the workpiece is always at the same, predefined distance from the transparent end face of the etching device, in particular during the etching process, which allows a particularly simple visual in-situ inspection in order to optimize the etching process simply and effectively.

In the following, directional information is described based on a cylindrical coordinate system; an axial direction corresponds to a vertical direction, with a radial direction and a circumferential direction each being oriented horizontally and thus perpendicularly to the axial direction.

To improve durability, the etching device can have a housing made of etch-resistant material, in particular in a region adjacent to the cavity. The housing can have a closable opening through which the workpiece to be processed can be introduced into the cavity. The workpiece can be attachable to a workpiece holder, which is produced in particular from an etch-resistant material, and the dimensions of which can be adapted to the dimensions of the etching device. When the workpiece is introduced into the cavity, the workpiece and/or the workpiece holder may come into contact with the lock at least in some regions and, during the subsequent etching process, remains in a position that can be predetermined by the position and/or the geometry of the lock.

Preferably, the at least one lock can be arranged such that the workpiece surface to be processed is oriented parallel to the transparent region of the end face facing the lock in order to avoid optical imaging errors.

Preferably, the lock can be arranged on a lateral inner wall of the cavity. In an example of the invention, the lock can be designed as at least one projection between the cavity and the gap. The gap can be a part of the cavity and/or connected to it. The lock can be designed as a projection directed toward the cavity, in particular radially inward, and multiple projections can be distributed around the circumference of the inner wall. Preferably, the lock can be annular or frame-shaped in the circumferential direction. As a result, a workpiece arranged in the cavity and/or the workpiece holder to which the workpiece can be attached can bear at the edge against the annular or frame-shaped lock and are reliably held thereon. In such an arrangement, the lock and the inner wall of the cavity on which the lock can be arranged can partially delimit the gap. At the same time, the gap can be delimited on one side by the workpiece and/or the workpiece holder, which bear at the edge against the lock. The workpiece surface to be etched can face the gap. In this way, etching liquid introduced into the gap can reach the workpiece surface to be processed, the workpiece assuming a geometrically predefined, reproducible position and being visible through the transparent region of the end face of the etching device facing the lock.

The transparent region of the end face facing the lock can be designed as a glass and/or plastic insert inserted into a depression in the end face, in particular as an inserted glass pane. In particular, the glass insert can contain an optical glass, which differs in its chemical composition from ordinary window glass and is commonly used to produce optical elements such as lenses, mirrors or prisms. The use of optical glass facilitates the optical monitoring of the etching process via the etching device according to the invention, in particular in combination with an optical sensor, which is designed as a microscope, for example. Transparent can mean to be a transmittance sufficient for visual inspection of the etching process for the specific wavelength range used, which includes the optically visible wavelength range but is not necessarily limited to it. The glass pane can correspond to the depression, be circular and/or arranged in a radially centered manner on the end face. Preferably, the glass pane can have a diameter between 90 mm and 100 mm and/or a thickness of approximately 1 mm.

Preferably, at least one clamping element can be provided in the cavity such that the workpiece that can be introduced into the cavity and/or the workpiece holder to which the workpiece can be attached can be clamped with the lock. For this purpose, the clamping element can be designed to apply a force directed toward the lock to the workpiece that can be introduced into the cavity and/or the workpiece holder. This ensures that even workpieces with different geometries always come into contact with the lock, so that the workpiece surface to be processed is at a predefined distance from the transparent region of the end face of the etching device. For example, the clamping element is movable, in particular linearly, in the direction of the lock.

In a particularly simple structural example, the clamping element can have at least one spring element, wherein the spring element can be designed as a helical and/or a metal spring. Alternatively or additionally, the clamping element can have a slide, in particular one that can be moved linearly, to which a force can be applied in the direction of the lock.

A workpiece receptacle can be arranged in the cavity in order to receive the workpiece to be processed and/or the workpiece holder that can be introduced into the cavity and to which the workpiece can be attached, wherein in particular the workpiece receptacle has the clamping element.

The workpiece receptacle can be used to hold the workpiece and/or the workpiece holder to which the workpiece can be attached in order to be able to position them in a defined position within the cavity. The workpiece receptacle preferably can have a stop edge for the workpiece, which stop edge limits the support surface of the workpiece laterally, i.e. radially, and predetermines the position of the workpiece. Preferably, the workpiece receptacle can have an interior with at least one clamping element with which the workpiece can be positioned and fixed for the etching process. The workpiece receptacle can be arranged in the cavity in such a way that the workpiece to be arranged thereon faces with its workpiece surface to be processed in the direction of the gap. The workpiece receptacle can be arranged completely in the cavity, in particular when the etching device is closed, and/or can partially protrude from the cavity when the etching device is open. The workpiece receptacle can be arranged movably in the cavity, in particular via a bearing, and/or can be fixed in a defined position via a fixing element. In an advantageous development of the invention, the workpiece receptacle is cylindrical, in particular hollow cylindrical.

The workpiece receptacle can be telescopic, for example in the form of in particular two cylinder sleeves that can be guided one inside the other and that form a common interior. The workpiece and/or the workpiece holder with the workpiece can be arranged in the interior of the workpiece receptacle via an opening in the end face. For the purpose of a space-saving design, the clamping element, in particular the helical spring, can be arranged in the interior of the workpiece receptacle and in particular can be movably guided over the inner wall of the workpiece receptacle. As a result, the inner wall of the workpiece receptacle can define a movement axis for the clamping element and the workpiece and/or the workpiece holder that can be positioned thereon.

The first cylinder sleeve of the workpiece receptacle can have a slightly larger inner diameter than the outer diameter of the second cylinder sleeve of the workpiece receptacle. This allows the cylinder sleeves to be guided in particular one over the other so that they can be displaced relative to one another over a common contact region and along a common longitudinal axis. Preferably, the workpiece receptacle is at least partially manufactured from etch-resistant material, for example polytetrafluoroethylene (PTFE).

A supply channel for the etching liquid that opens into the cavity, in particular into the gap, can be designed to widen, in particular continuously, at least in portions in the direction of the cavity, in particular in the direction of the gap. For example, the side walls in the widening portion of the supply channel are not oriented parallel to one another but enclose a finite, acute angle between them. Preferably, the supply channel can be designed to widen over a horizontal, in particular radial, portion. The etching liquid can pass via the supply channel into the gap and thus to the surface to be processed of the workpiece. It has been found that the widening design of the supply channel significantly reduces the formation of air bubbles in comparison with a supply channel with a constant width. The etching process is improved by the resulting homogenization of the etching liquid. The supply channel can be formed in particular in portions between the lock and the end face of the etching device facing the lock; the diameter of the supply channel can be larger than the diameter of the discharge channel, in particular in a portion directed toward the gap. Preferably, the supply channel, in particular its horizontal, most preferably its widening portion, can be designed as a groove, which is surrounded by the side walls and has, for example, a depth of 1 mm.

The clamping element can be electrically conductively connected to an electrical connection in order to electrically contact the workpiece that can be introduced into the cavity. This makes possible an electrolytic etching process, also known as electroetching, using the etching device according to the invention. In this case, the surface to be processed of the workpiece is removed using an electric current. This allows electrical contact to be made with the workpiece. With this type of etching, less corrosive etching liquids can be used to process the workpiece compared to purely chemical etching. The etching liquid is used as an electrolyte, and the workpiece electrically connected to the connection is used as an electrode, in particular as an anode. It is within the abilities of a person skilled in the art to immerse a second electrode, preferably formed of precious metal, as a cathode in the etching liquid at a suitable position inside or outside the etching device. Preferably, the cathode can be arranged in the cavity in such a way that the cathode is electrically conductively connected to the etching liquid during the etching process. The cathode can be detachably connected to the etching device so that the cathode is exchangeable. A structurally simple development of the invention can provide for the cathode to be cylindrical.

When a voltage is applied between the anode and the cathode, a current flows, and ions are released from the anode, in this case the workpiece, and pass to the cathode through the etching liquid acting as the electrolyte. The ions of the workpiece separate or precipitate out of the solution as a precipitate on the cathode. The workpiece surface is thereby etched at the desired locations.

The cathode can be arranged within the cavity such that it has no mechanical contact with the workpiece during the electrolytic etching process, in order to avoid an electrical short circuit.

For example, a heating element can be arranged in the cavity, which heating element is designed to heat the etching liquid introduced into the gap to a user-defined temperature. This makes it possible also to etch the workpiece thermally. Such an etching method is based on the finding that the result of the etching process can be significantly influenced and controlled, and thus optimized, by a desired temperature control of the etching liquid. For this purpose, the heating element can be simply arranged in the cavity of the etching device and/or designed as a heating plate.

The heating element can be designed as an electrical heating element that can convert supplied electrical energy into heat. In a structurally simple example of the invention, the heating element can be arranged in the region of the supply channel so that the etching liquid can be heated to a user-defined temperature as it flows through the supply channel in the direction of the workpiece to be processed and can come into contact with the workpiece in this state. The heating element can be designed as a heating plate, which is arranged in particular in the workpiece receptacle.

In addition to the heating element, at least one temperature sensor can be provided to determine and monitor the temperature of the etching device, in particular of the etching liquid. Preferably, the cavity and/or the workpiece receptacle can have the temperature sensor, preferably in its interior. Preferably, a magnetic stirrer or a rotatable flow propeller can be provided, which are designed to bring about uniform wetting of the workpiece surface with etching liquid. For this purpose, the magnetic stirrer and/or the flow propeller can be arranged in an etching liquid line, arranged upstream of the gap, and/or in the supply channel. This makes it possible to achieve uniform and homogeneous material removal on the workpiece surface to be etched, which can be referred to as the workpiece sample. Viewed microscopically, the ions of the workpiece that are created as a result of the etching process are transported away in an optimized manner, so that static effects that disrupt the etching process are avoided and, as a result, a reproducible etching result can also be obtained. The heating element can be arranged in the cavity of the etching device, for example as a heating plate, and/or connected to the clamping element.

Preferably, a support surface of the etching device, which is designed in particular as at least one foot, can have a pressure sensor. A pressure sensor can determine a force directed onto the etching device in the direction of a base on which the etching device is arranged. The pressure sensor thus usually registers the weight force of the etching device but also a force that is increased compared to this if, for example, external components are placed on the etching device or come into contact with it. In particular, each foot has a pressure sensor. The pressure sensor can be connected to an evaluation unit that reads the force determined by the pressure sensor and compares it with a defined limit value so that, for example, if the limit value is exceeded, a warning signal is output that indicates imminent damage to the etching device as a result of the force acting on it. The warning signal can be visual and/or acoustic. In this way, in particular when an optical sensor comes into contact with the transparent region of the etching device during the inspection of the etching process, the warning signal can be output before the optical sensor destroys the transparent region of the end face and etching liquid leaks out of the etching device as a result.

In an advantageous development of the invention, the etching device is designed in two parts, wherein a lower part of the etching device in particular can comprise at least part of the cavity, and/or an upper part of the etching device can comprise the lock and/or the gap. The upper part of the etching device can be designed to close the cavity, wherein, in a closed state of the etching device, the upper part can comprise the end face that faces the lock and has the transparent region. In addition, the lock can be arranged on a side of the upper part facing the cavity, in particular between the cavity and the gap.

The lower part of the etching device can comprise the support surface, in particular the at least one foot, in a structurally simple manner. The etching device, in particular the upper part and/or the lower part, can be cylindrical, although alternatively cuboid, in particular cube-shaped, designs can also be provided.

The upper part can be designed as a cover element for the lower part, with which the cavity of the lower part can be either tightly closed or opened again. Preferably, the upper part can have an outer contour corresponding to the lower part, so that the outside of the upper part bears flush against the outside of the lower part when the lower part is connected to the upper part, in particular closed. This allows easy handling of the etching device according to the invention. Preferably, an etch-resistant seal, which is designed as a sealing ring, for example, can be provided in a region between the upper part and the lower part. To close the cavity, the lower part and the upper part can have closure elements arranged on their respective outer sides and corresponding to one another, so that the lower part can be detachably connected to the upper part, in particular in a force-fitting and/or form-fitting manner. Preferably, at least one quick release can be provided to clamp the upper part to the lower part.

Preferably, the lock may always be at a predefined distance from the end face facing the lock, wherein for this purpose in particular the upper part can have the at least one lock.

In an advantageous development of the invention, the upper part has the supply channel, and the lower part has an etching liquid supply line, wherein the etching liquid supply line is connected to the supply channel in the closed state of the etching device. The diameter of the etching liquid supply line can correspond to the diameter of the supply channel, in particular in a portion directed toward the etching liquid supply line. This makes it possible to direct etching liquid via the etching liquid supply line and the supply channel into the gap at the surface to be processed of the workpiece. The etching liquid supply line can remain connected to an etching liquid source even if the upper part is removed from the lower part because a workpiece is being exchanged. In comparison with a supply of the etching liquid exclusively via the upper part, the etching liquid-carrying connections required for this are not adversely affected by the movements of the upper part, for example when the cavity is opened or closed. The etching liquid supply line can be designed as a glass tube, at least in portions, or can be connected to such a glass tube.

Preferably, at least one optical sensor of the etching device can be arranged such that the workpiece that can be introduced into the cavity can be detected by the optical sensor at least partially through the transparent region, in order to be able to inspect the etching process visually. The optical sensor can be designed as an optically magnifying system and/or use electromagnetic radiation in the infrared, ultraviolet and/or visible spectrum to inspect the workpiece. In an advantageous development of the invention, the optical sensor is designed as a microscope, in particular as an objective of a microscope, which can be movable in particular in the direction of the workpiece. In addition, the optical sensor can have a camera, in particular a video camera, to store and process image information of the workpiece. The optical sensor can be arranged at an in particular variable distance from the end face facing the lock. The optical sensor can also be designed to output a warning signal when the optical sensor falls below a predefined distance from the transparent region of the end face and/or touches it.

The etching liquid source of the etching system according to the invention can be designed in a simple manner as a sealable container that has an etch-resistant surface and is used for the storage of etching liquids. The etching system can have a plurality of such etching liquid sources, which can be connected to one another via a line system, which can in particular have at least one valve and at least one supply line. The at least one valve can be designed as a two-way valve.

The etching system according to the invention can have at least one pump device and/or at least one valve device, which is at least indirectly connected to the etching liquid supply line and/or to the etching liquid discharge line in order to conduct etching liquid to the gap and/or away from the gap at an in particular predefined flow rate. Via the pump device and/or the valve device, the flow of the etching liquid can be controlled in a user-defined manner, for example to start and/or end the etching process in a user-defined manner.

The pump device comprises at least one pump and is connected in particular via the valve device to the at least one etching liquid source as well as to the supply channel and to the etching liquid supply line in order to convey etching liquid from the etching liquid source via the etching liquid supply line and the supply channel into the gap. In addition, the pump device can be connected to the supply channel, the discharge line and the etching liquid reservoir in order to conduct the etching liquid from the gap to the etching liquid reservoir in a user-defined manner after the etching process. The pump device is designed in particular to be electrically controllable and can allow the setting of a volume- and/or pressure-controlled etching liquid flow.

The valve device comprises at least one controllable valve, in particular a solenoid valve, which can be designed as a shut-off, directional or mixing valve. The at least one controllable valve can be designed as a two-way valve. The valve device can be electrically controllable. Via the valve device, the etching liquid flow can be released or blocked in a simple manner via an electrical signal, in particular in a user-defined manner, in order to start, interrupt and/or end the etching process of the etching device.

In an advantageous development of the invention, the valve device and/or the pump device is connected to multiple etching liquid sources in order to convey the etching liquid into the gap in a user-defined mixing ratio. At least one mixing valve can be provided for this purpose. In addition, a rinsing liquid source can be provided to conduct a rinsing liquid located in the rinsing liquid source, in particular via the pump device and/or the valve device, into the gap in a user-defined manner, in order to interrupt the etching process and to convey the etching liquid out of the gap in a controlled manner.

The pump device and/or the valve device can be connected to a control unit such that the etching liquid can be introduced into the etching device with a user-defined process parameter, wherein the process parameter comprises at least one parameter from the following group: composition of the etching liquid, flow rate of the etching liquid, density of the etching liquid, time of supply of the etching liquid into the gap, time of drainage of the etching liquid out of the gap.

The control unit can be designed to control the pump device and/or the valve device with a predetermined clock frequency. The composition of the etching liquid conducted to the gap can be controlled in a user-defined manner via the control unit, in particular via the mixing valves mentioned. In addition, the control unit can be connected to the electrical connection and/or to the heating element in order to control the electrical and/or thermal etching process.

An advantageous development of the invention can provide for the heating element, as part of the etching system, to be arranged outside the etching device in such a way that the temperature of the etching liquid is controlled before and/or while it enters the etching liquid supply line and/or the supply channel.

The etching device and/or at least one component of the etching system can be arranged in a drip tray in order to protect the environment from any escaping etching liquid in the event of a leak.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows an example of an etching device according to the invention in a view from the front, in which a lower part and an upper part of the etching device are shown separated from one another;

FIG. 2 shows the etching device according to FIG. 1 with the lower part and upper part assembled;

FIG. 3 shows the etching device according to FIG. 1 in a section;

FIG. 4 shows the etching device according to FIG. 2 in a section;

FIG. 5 shows the upper part of the etching device according to FIG. 1 in a view from above;

FIG. 6 shows the upper part according to FIG. 5 in a view from below;

FIG. 7 shows the lower part of the etching device according to FIG. 1 in a view from above;

FIGS. 8A and 8B shows a workpiece receptacle of the etching device according to FIG. 1 in FIG. 8A a view from the front and FIG. 8B a view from above;

FIG. 9 shows an example of an etching device according to the invention with an optical sensor in a sectional view from the front;

FIG. 10 shows an example of an etching device according to the invention for electrolytic etching;

FIG. 11 shows an example of an etching device according to the invention for thermal etching;

FIG. 12 shows part of an etching system in a side view;

FIG. 13 shows the part of the etching system according to FIG. 12 in a section;

FIG. 14 shows the part of the etching system according to FIG. 12 in a view from above;

FIG. 15 shows the part of the etching system according to FIG. 12 in a view from behind;

FIG. 16 shows an example of the etching device according to the invention in a side view;

FIG. 17 shows the etching device according to FIG. 16 in a section; and

FIG. 18 shows the etching system according to FIGS. 13 to 15, which has an etchant circuit.

### DETAILED DESCRIPTION

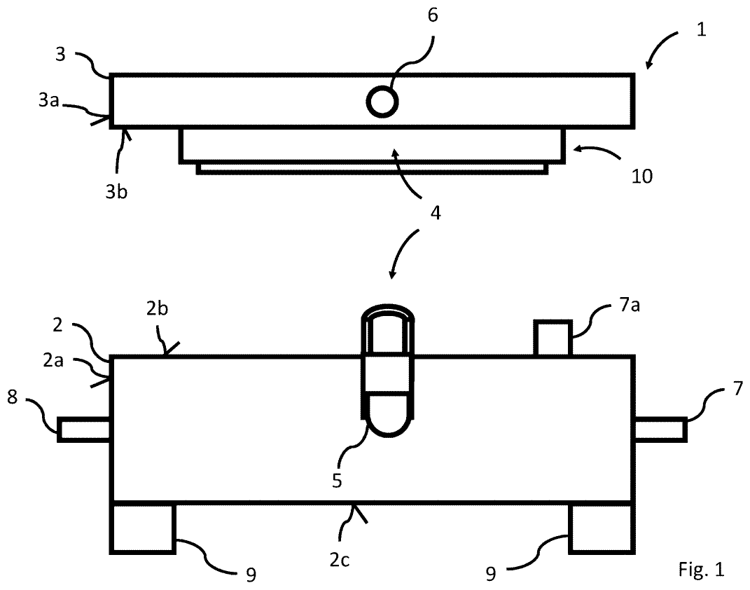

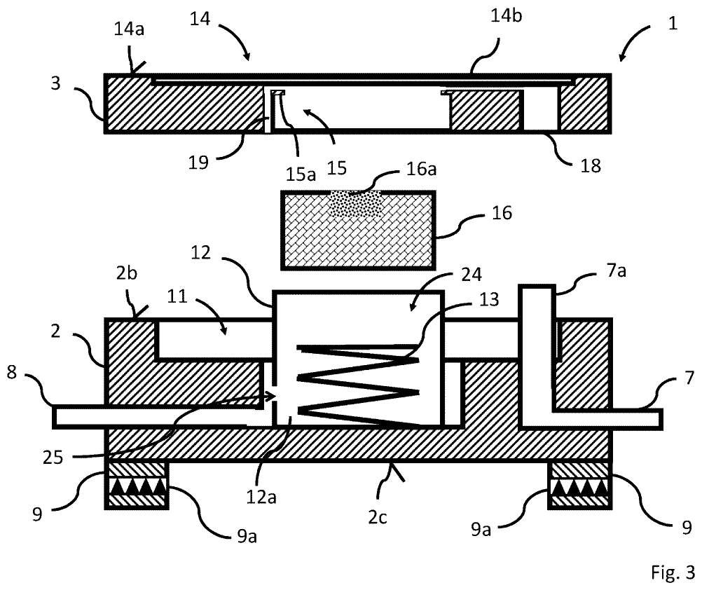

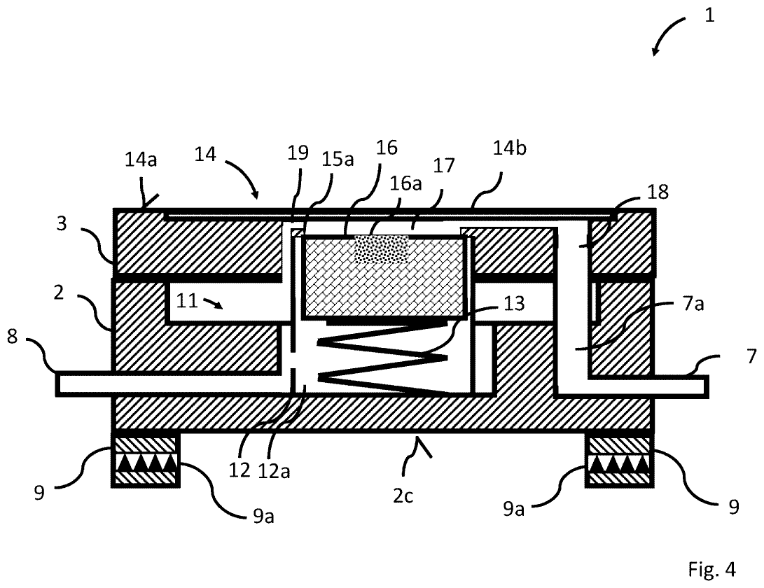

FIG. 1 shows an example of an etching device 1 according to the invention, which is used for the chemical processing of a workpiece 16 via an etching liquid. The etching device 1 is formed in two parts and is approximately cylindrical in shape and comprises a lower part 2 and an upper part 3, the upper part 3 being designed to close a cavity 11 formed in the lower part 2 (see FIGS. 3 and 4). The etching device 1 has a quick-release fastener 4, which comprises a clamping clip 5 and a projection 6 corresponding thereto. The clamping clip 5 is arranged on the radial lateral surface 2a of the lower part 2, while the projection 6 is arranged on the radial lateral surface 3a of the upper part 3.

The lower part 2 has an etching liquid supply line 7 and an etching liquid discharge line 8. The etching liquid supply line 7 runs radially through the lateral surface 2a of the lower part 2 and opens into a vertically oriented glass tube 7a, which passes through the cavity 11, projects beyond an upper end face 2b of the lower part 2, and is directed toward the upper part 3 as shown in FIG. 1. The etchant discharge line 8 likewise runs through the lateral surface 2a of the lower part 2 and opens into the cavity 11 thereof. On an underside 2c of the lower part 2 facing away from the upper part 3, feet 9 with support surfaces are provided.

The upper part 3 has a centering guide 10 on the underside 3b facing the lower part 2, via which centering guide the upper part 3 can be positioned in a radially centered manner on the lower part 2 and inserted into same with a tight fit. For this purpose, the centering guide 10 has a slightly smaller diameter than the inner diameter of the cavity 11. The centering guide 10 has a radially laterally arranged seal, which is resistant to chemicals and corrosion. For better clarity, the centering guide 10 is no longer shown in the following figures.

The etching device 1 shown in FIG. 1 is in a loading state in which a workpiece 16 can be positioned within the lower part 2 on a helical spring 13 in a cylindrical, etch-resistant workpiece receptacle 12 of the lower part 2. This state is explained with reference to FIG. 3.

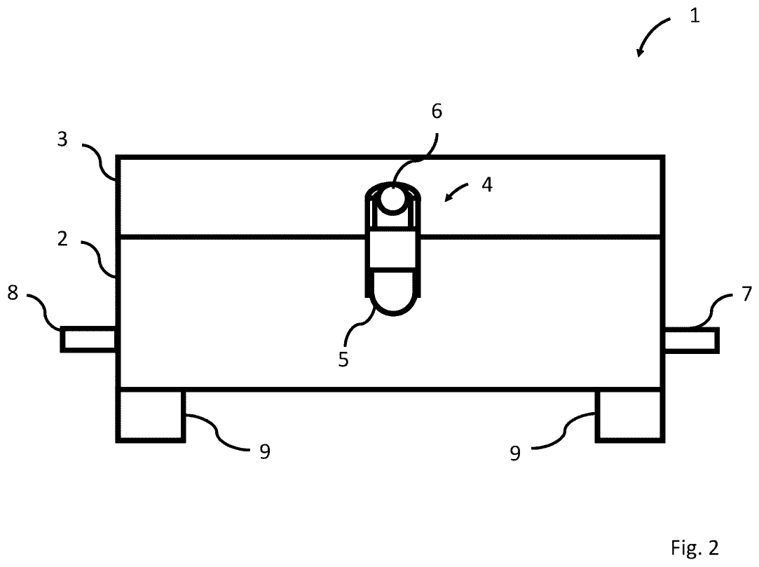

FIG. 2 shows the etching device 1 according to FIG. 1 with the lower part 2 and the upper part 3 in an assembled state, in which the clamping clip 5 and the projection 6 are clamped to one another. According to FIG. 2, the etching device 1 is in an operating state, which is explained with reference to FIG. 4.

FIG. 3 shows the etching device 1 according to FIG. 1, i.e., in the loading state, in a section. According to the illustration in FIG. 1, the upper part 3 is shown detached from the lower part 2 and raised. The lower part 2 has the cavity 11 in the upper end face 2b. As already mentioned, the workpiece receptacle 12 is arranged in the cavity 11 and in the example shown here is hollow and has an opening 24 in its upper end face on a side facing the upper part 3 in order to receive the workpiece 16.

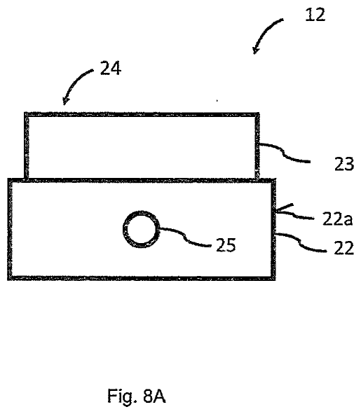

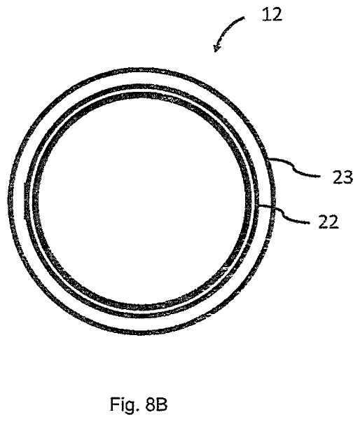

Within the workpiece receptacle 12 there is a clamping element in the form of a metallic helical spring 13, on which the workpiece 16 can be positioned. At an end remote from the upper part 3, the helical spring 13 is rigidly connected to the workpiece receptacle 12. The workpiece receptacle 12 is shown in detail in FIGS. 8A and 8B and is described in detail below.

The upper part 3 has on its axially upper end face 14a a transparent region 14, which is designed here as optical glass 14b, which is arranged as an insert part flush with the end face 14a of the upper part 3 and rests on the upper part 3 on a region that in this respect serves as a support surface. An annular lock 15 is formed here on the upper part 3. When the cavity 11 is open—the etching device 1 is in the loading state-a workpiece 16 to be etched with a workpiece sample 16a to be etched and examined is positioned in the workpiece receptacle 12 and on the helical spring 13. The upper part 3 is then placed on the lower part 2 and clamped to it in order to close the cavity 11. In the process, the lock 15 comes into mechanical contact with an edge region of the workpiece 16. The closing movement of the upper part 3 is transmitted to the workpiece 16 and to the helical spring 13 via the lock 15, whereby the spring is mechanically loaded and serves as a clamping element. When the cavity 11 is closed—the etching device 1 is in the operating state—the workpiece 16 is thus clamped between the helical spring 13 and the lock 15 and is subjected to a force directed axially upward toward the lock 15. This is shown in FIG. 4.

The lock 15 is designed as an annular, circumferential radial projection 15a; when the cavity 11 is closed, a gap 17 is formed axially between the transparent region 14 of the upper part 3 and the surface of the workpiece 16, the projection 15 being arranged between the cavity 11 and the gap 17, and the surface of the workpiece 16 being oriented parallel to the end face 14a, in particular parallel to the surface of the inserted glass 14b. This is advantageous because the surface of the workpiece 16, in particular the surface of the workpiece sample 16a to be examined, can be uniformly clearly seen through the transparent region 14, and a microscope can be used as an optical sensor 26 to monitor the workpiece 16 during the etching process. Due to the clamping element 13, which is designed as a helical spring 13, the workpiece surface to be processed is always at a structurally predefined-axial-distance from the glass 14b. This allows a reliable inspection of the workpiece 16 even in situ during the etching process. The optical axis of the optical sensor 26 corresponds to the axial direction.

According to FIG. 4, when the etching device 1 is closed, i.e., in particular when the cavity 11 is closed by the upper part 3, the etching liquid supply line 7 opens via the glass tube 7a into a supply channel 18 of the upper part 3. The diameter of the etching liquid supply line 7 and the diameter of the glass tube 7a each correspond to the diameter of the portion of the supply channel 18 directed toward it. The supply channel 18 extends through the upper part 3 and opens into the gap 17. As a result, the etching liquid reaches the surface to be etched of the workpiece 16. Via a discharge channel 19, the etching liquid can be conducted together with the dissolved components of the workpiece 16 out of the gap 17 into the cavity 11 and via the etching liquid discharge line 8 of the lower part 2 out of the etching device 1.

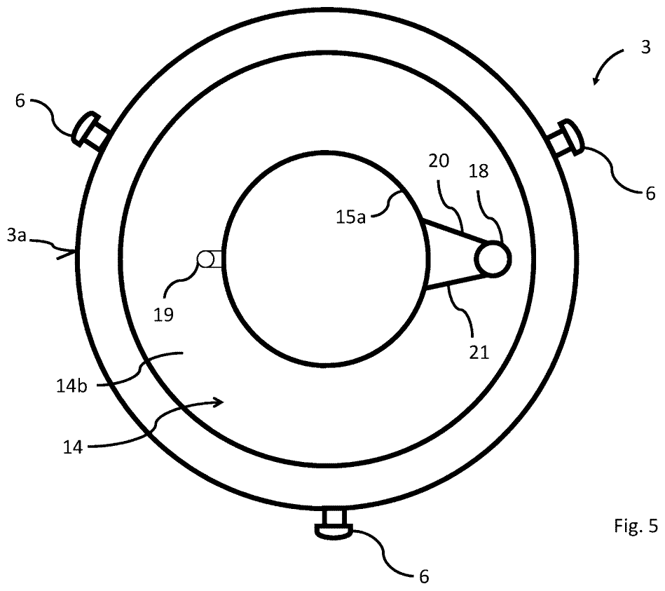

FIG. 5 shows the upper part 3 in a view from above, in which it can be seen that the upper part 3 has a substantially circular outer contour, on the radially outer lateral surface 3a of which a total of three projections 6 are evenly distributed around the circumference. The transparent region 14 also has a substantially circular outer contour and is inserted into the upper part 3 as optical glass 14b in the manner already explained. Due to the transparency of the optical glass 14b that forms the transparent region 14, the supply channel 18, which is formed axially below the transparent region 14, is visible in the view from above of FIG. 5. The supply channel 18 has a portion that runs substantially axially below the optical glass 14b and is laterally delimited by two walls 20, 21. In this portion, the supply channel 18 is designed as a 1 mm-deep groove, which is surrounded by the walls 20, 21. The walls 20, 21 are spaced apart from one another at a distance that increases in the direction of the gap 17 and thereby form an acute angle between them, so that the supply channel 18 widens in the direction of the gap 17. As a result, the flow properties of the etching liquid flowing through the supply channel 18 to the workpiece 16 are improved, and in particular the formation of air bubbles in the gap 17 is avoided. The discharge channel 19 of the upper part 3 is also visible in FIG. 5 and has a constant diameter, which is smaller than the diameter of the supply channel 18, in the region visible in FIG. 5.

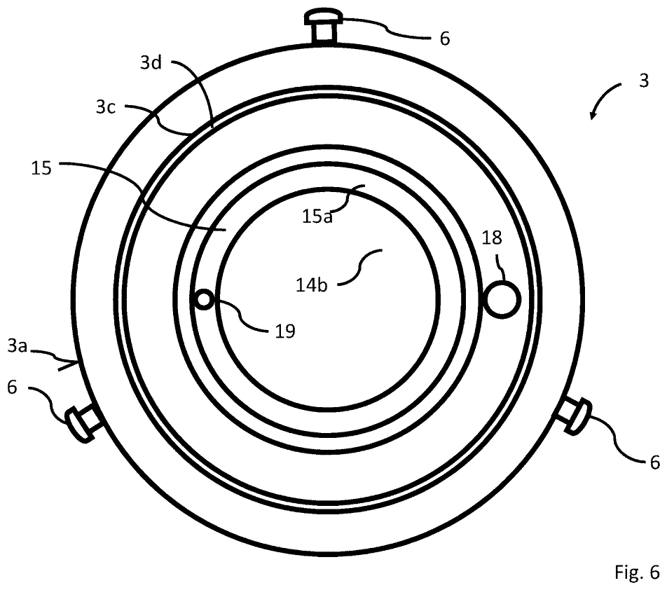

FIG. 6 shows the upper part 3 of FIG. 5 in a view from below. The supply channel 18 is arranged in such a way as to communicate with the glass tube 7a and with the etching liquid supply line 7 of the lower part 2 when the cavity 11 of the lower part 2 is closed. The discharge channel 19 opens into the cavity 11 of the lower part 2, which is closed by the upper part 3. In FIG. 6, only the part of the optical glass 14b that is surrounded by the annular projection 15a of the lock 15 can be seen. The underside of the upper part 3 of FIG. 6 has an annular groove 3c radially approximately centrally between the lock 15 and the lateral surface 3a, into which groove a sealing ring 3d is inserted in order to seal off the cavity 11 of the lower part 2 from the outside when the etching device 1 is assembled.

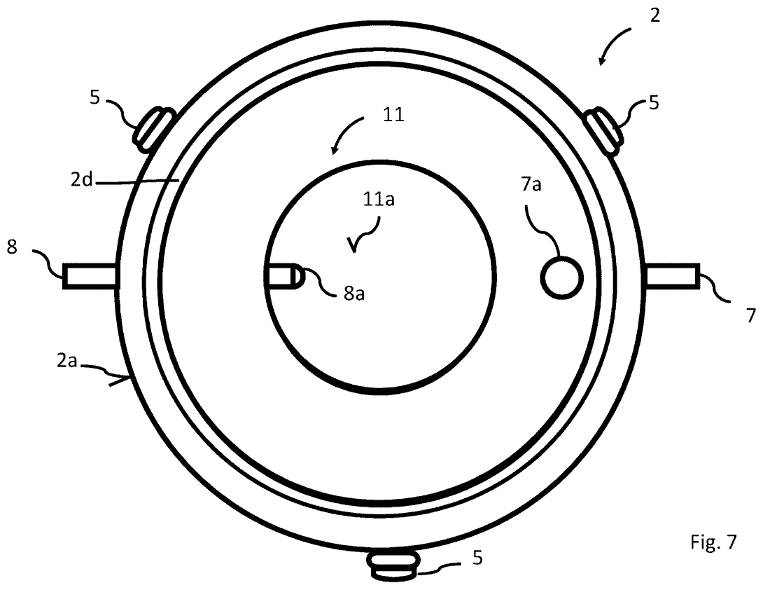

FIG. 7 shows the lower part 2 of the etching device 1, which has the cylindrical lateral surface 2a corresponding to the upper part 3, on which three clamping clips 5 are evenly distributed over the circumference. The clamping clips 5 are designed to correspond to the projections 6 of the upper part 3. In the view from above of FIG. 7, the cavity 11 of the lower part 2 is exposed. As already explained, the etching liquid supply line 7 serves to convey etching liquid into the supply channel 18 of the upper part 3. The etching liquid discharge line 8 serves to guide the etching liquid emerging from the discharge channel 18 of the upper part 3 out of the cavity 11 of the lower part 2. As can be seen in FIG. 7, the etchant discharge channel 8 is partially designed as a groove 8a, which is formed in a bottom 11a of the cavity 11 and runs through the lateral surface 2a of the lower part 2. The upper side of the lower part 2 according to FIG. 7 has an annular groove 2d, which corresponds to the annular groove 3c of the upper part 3 and is therefore also designed to receive the sealing ring 3d when the etching device 1 is closed.

In example of the etching device 1, the discharge channel 19 of the upper part 3 can open directly into the etchant discharge line 8 of the lower part 2, in which case the etchant discharge line 8, analogously to the etchant supply line 7, can partially have a glass or plastic tube or can be connected to a glass or plastic tube.

FIG. 8A shows a view from the front and FIG. 8B shows a view from above of the workpiece receptacle 12. The workpiece receptacle 12 has a stepped hollow cylinder shape with a lower cylinder part 22 and an upper cylinder part 23, the upper cylinder part 23 having a smaller diameter than the lower cylinder part 22. Both cylinder parts 22 and 23 are designed as sleeves and delimit the interior 12a, which is shown in FIG. 3 and in which the already described clamping element in the form of the helical spring 13 can be arranged. The upper cylinder part 23 has, in the end face, the opening 24 through which the workpiece 16 can be inserted and placed on the helical spring 13 positioned in the workpiece receptacle 12. The cylinder parts 22, 23 are produced from polytetrafluoroethylene (PTFE).

The lower cylinder part 22 has an opening 25 in its lateral surface 22a, which opening exposes the interior 12a of the workpiece receptacle 12. The etching liquid conducted out of the discharge channel 19 into the cavity 11 of the lower part 2 can reach the interior 12a of the workpiece receptacle 12 via the opening 25 and can flow out of the workpiece receptacle 12 again through the opening 25. The interior 12a of the workpiece receptacle 12 is thus not sealed off from the cavity 11 of the lower part 2.

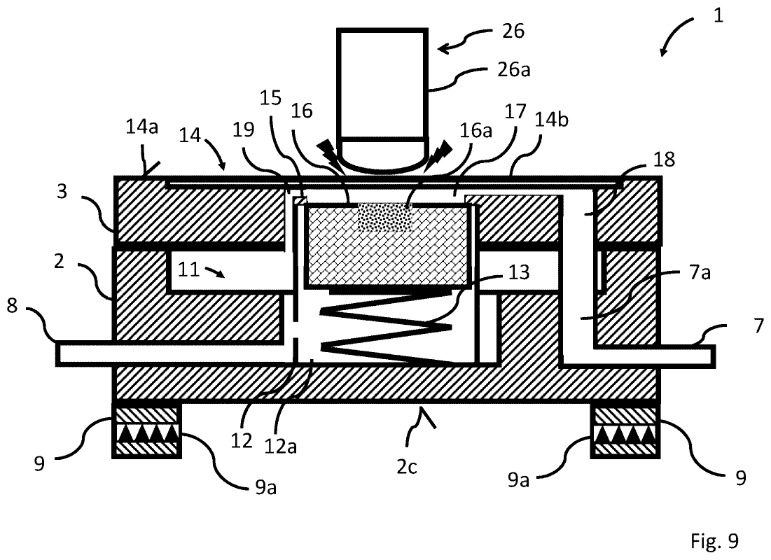

FIG. 9 shows example of the etching device 1 according to the invention, which is substantially identical in structure to the first example of the etching device 1 and has correspondingly identically constructed components (cf. FIGS. 1 to 8).

The etching device 1 according to FIG. 9 has an optical sensor 26 arranged axially above the glass 14b for the visual inspection of an etching process, which optical sensor is designed in the example shown as a schematically represented microscope 26;

FIG. 9 shows an axially movable objective 26a of the microscope 26 in order to visually inspect the etching process, in particular in situ. During the axial movement of the objective 26a, there is a risk that the objective 26a will come into contact with the glass 14b and, if the movement continues, break it, which would cause serious damage, in particular due to the etching liquid that would then escape. To avoid damage to the etching device 1, its feet 9 each have a pressure sensor 9a. The pressure sensors 9a are designed to determine a force directed against the base. During normal operation, this force corresponds to the weight force of the etching device 1. However, if the objective 26a comes into contact with the glass 14b, the force determined by the pressure sensors 9a increases. In this case, it is provided for a warning signal to be output to alert a user to imminent damage to the etching device 1.

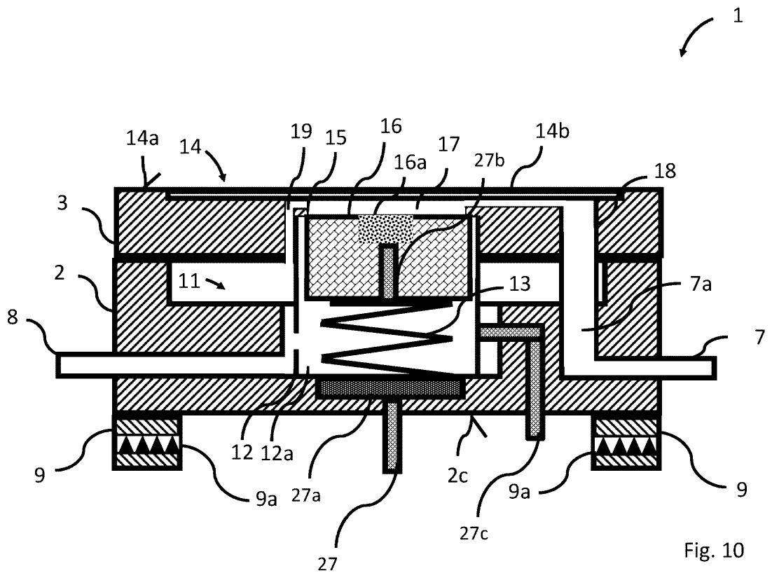

FIG. 10 shows the etching device 1 according to the invention in an example, which is similar to the design according to FIG. 9 and accordingly has some identically constructed components. In contrast to the example of FIG. 9, the helical spring 13 is electrically conductive and is contacted with the electrically conductive metal plate 27a of the lower part 2. The helical spring 13 has on its side facing the workpiece 16 an electrical contact 27b, which is in contact with the workpiece 16 and serves to electrically contact the workpiece 16. The workpiece receptacle 12 is also electrically conductive and can also be electrically contacted via a second connection 27c, so that an electrical voltage can be applied to the workpiece 16 to be etched. This makes the etching device of FIG. 10 suitable for electrolytic etching of the workpiece 16.

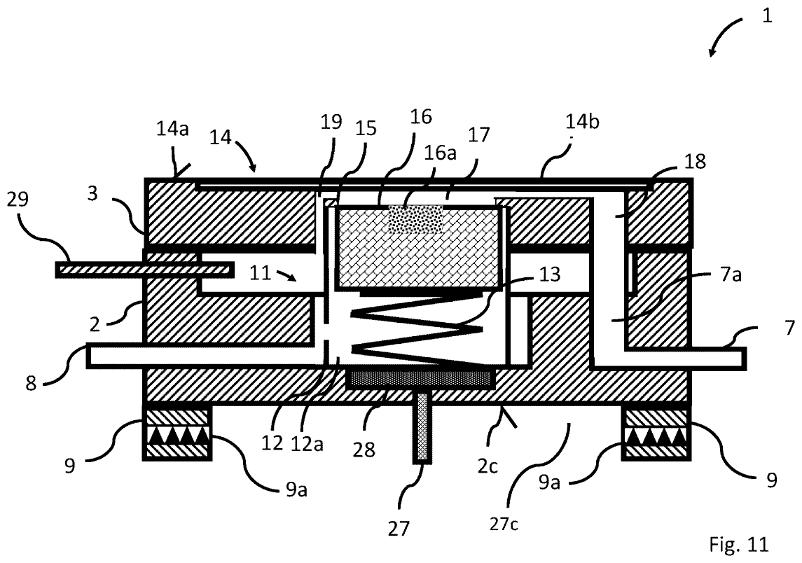

FIG. 11 shows an example of the etching device 1 according to the invention, which is similar in structure to the example of FIG. 10 and accordingly has some identically constructed components. In contrast to the etching device 1 shown in FIG. 10, the etching device 1 of FIG. 11 has an electric heating plate 28 as a heating element, which is arranged on the lower part 2 and within the workpiece receptacle 12, and a temperature sensor 29, which passes radially through the lower part 2 at the axial height of the workpiece 16 and projects into the cavity 11. The heating plate 28 converts supplied electrical energy into heat and is electrically connected to the electrical connection 27 of the lower part 2. In the example shown here, the heating plate 28 is thermally conductively connected to the etching liquid in the gap 17 via the spring element 13 and the workpiece 16 in order to control and regulate the temperature of the etching liquid in a user-defined manner.

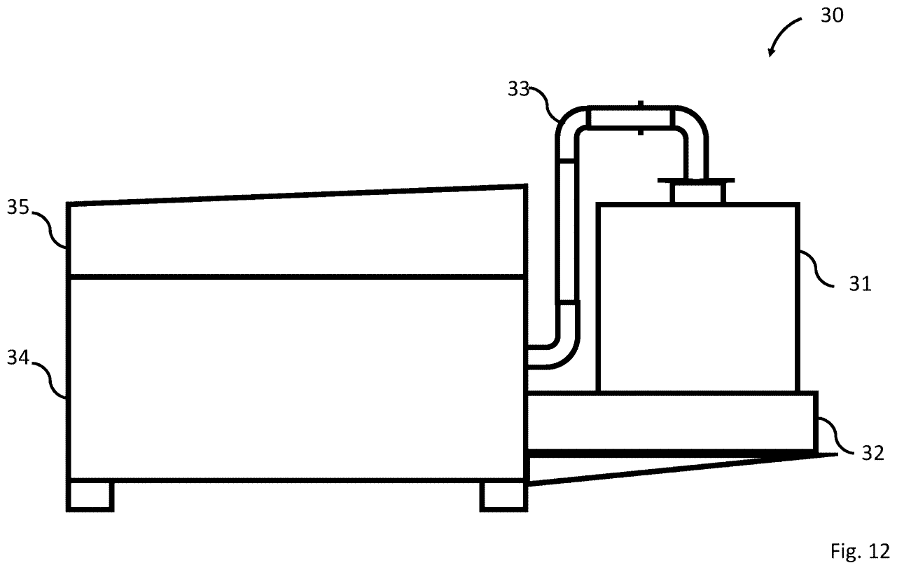

FIG. 12 shows a part of an etching system 30 according to the invention, which, in addition to the etching device 1 and an etching liquid reservoir 48 (not shown in FIG. 12), has four etching liquid sources 31, of which only one etching liquid source 31 is visible in FIG. 12 due to the perspective. The etching liquid sources 31 are arranged inside a tray 32 so that, in the event of a leakage from the etching liquid sources 31, escaping etching liquid is collected in the tray 32, and further damage to the environment is avoided.

The etching liquid sources 31 are each connected via an etching liquid line 33 to a housing 34 in which a pump device 38 and a valve device 39 are arranged; the pump device 38 and the valve device 39 are not shown in FIG. 12. The housing 34 further comprises a control unit 37 (also not visible in FIG. 12), with which the pump device 38 and the valve device 39 can be controlled in order to convey etching liquid from the etching liquid source 31 to the etching device 1. The housing 34 comprises a cover 35 in which an input unit 36 designed as a control panel (not shown in FIG. 12) is integrated. The input unit 36 is connected to the control unit 37 for signal transmission and allows the components arranged in the housing 34 to be controlled in order to operate the etching device 1.

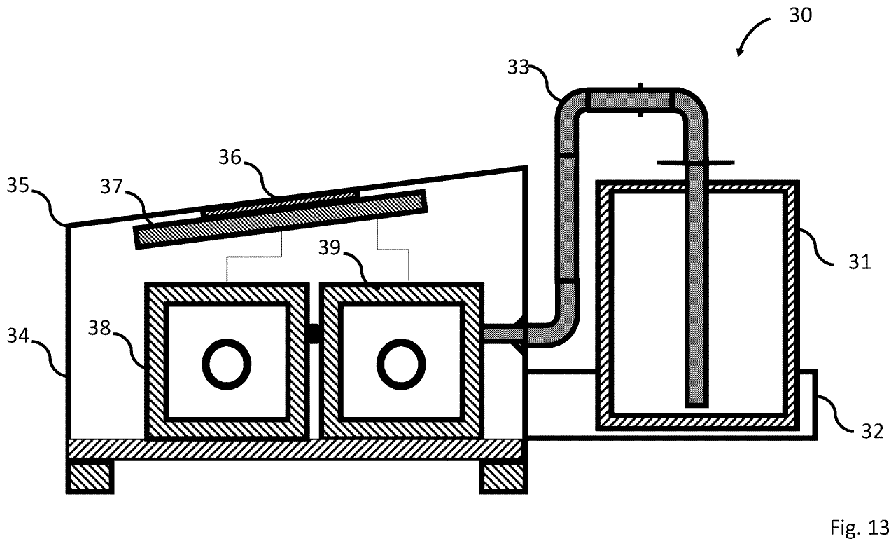

FIG. 13 shows the part of the etching system 30 shown in FIG. 12 in a schematic section, according to which the pump device 38 arranged in the housing 34 and the valve device 39 can be seen. In the example shown here, the valve device 39 is a directional valve via which etching liquid is conducted from at least one of the four etching liquid sources 31 to the pump device 38. The control panel 36 is arranged on a side of the cover 35 facing away from the housing and is connected to the control unit 37, which has a microcontroller. The signal connections from the control unit 37 to the pump device 38 and the valve device 39 make it possible to control the latter two. The control can take place in a time-controlled manner so that the etching process can be started and ended at user-defined times. The pump device 38 is connected to the etchant supply line 7 of the etching device 1 according to the invention (not shown in FIG. 13).

In an example, the valve device 39 is designed as a mixing valve, with which it is possible to convey the etching liquids located in the etching liquid sources 31 to the etching device 1, in particular into the gap 17 thereof, in a definable ratio. The mixing ratio can be set via the control panel 36. A time sequence for the etching process can also be set via the control panel 36. One of the etching liquid sources 31 can be filled with a rinsing liquid, which can be controlled in a user-defined manner via the control unit 37 in such a way that the etching process is promoted in particular in a user-defined manner by supplying the rinsing liquid into the gap 17 of the etching device 1. In this way, the etching process can be ended in a controlled manner.

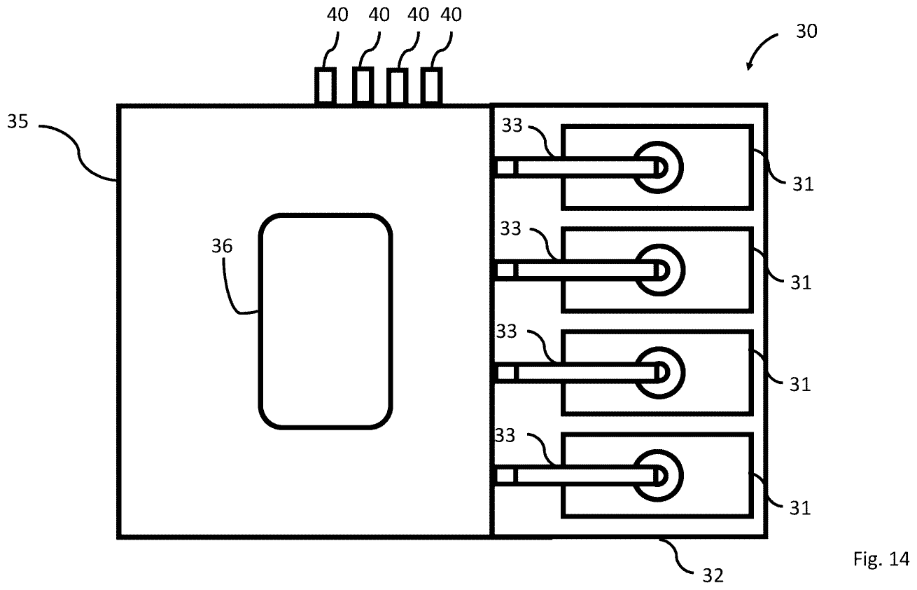

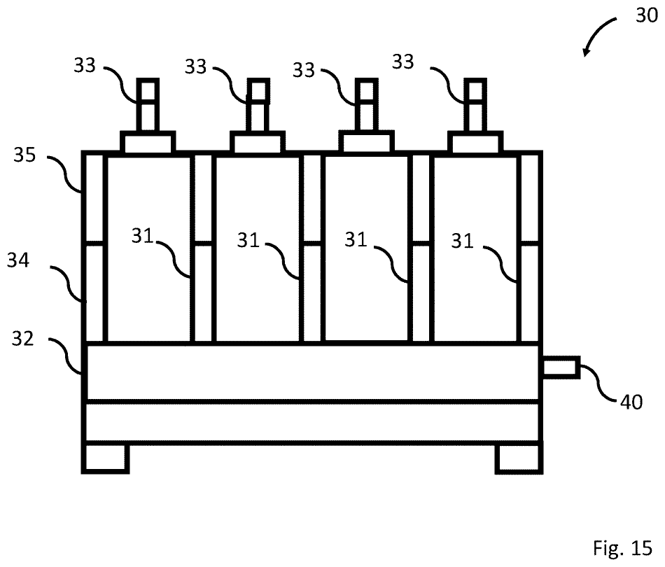

FIG. 14 shows the part of the etching system 30 according to FIGS. 12 and 13 in a view from above, from which the four etching liquid sources 31 can be seen, which, as already mentioned, are each connected via an etching liquid line 33 to the valve device 39 within the housing 34 of the etching system 30. Etching liquid can be conveyed to the etching device 1 according to the invention via supply lines 40. FIG. 15 shows the part of the etching system 30 of FIGS. 12 to 14 in a view from behind, from which in particular the arrangement of the etching liquid sources 31 in the tray 32 can be seen.

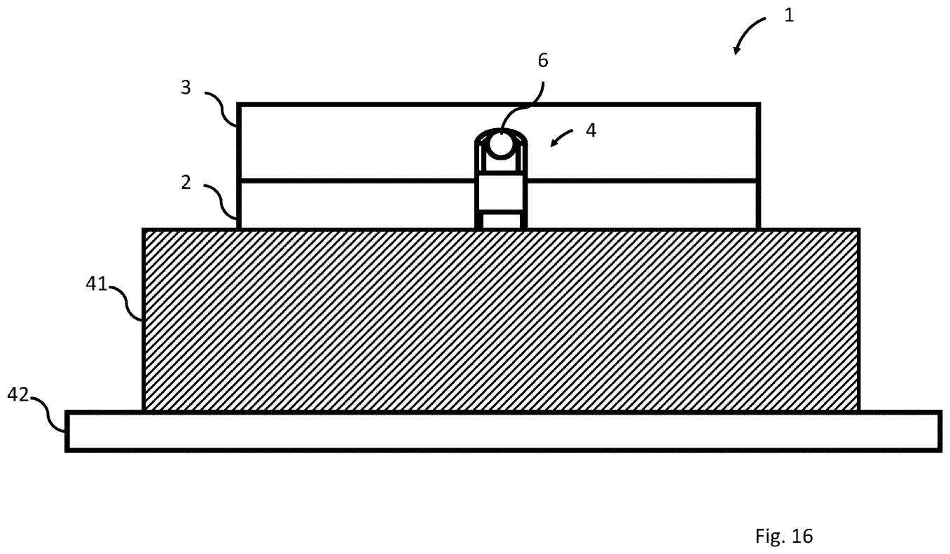

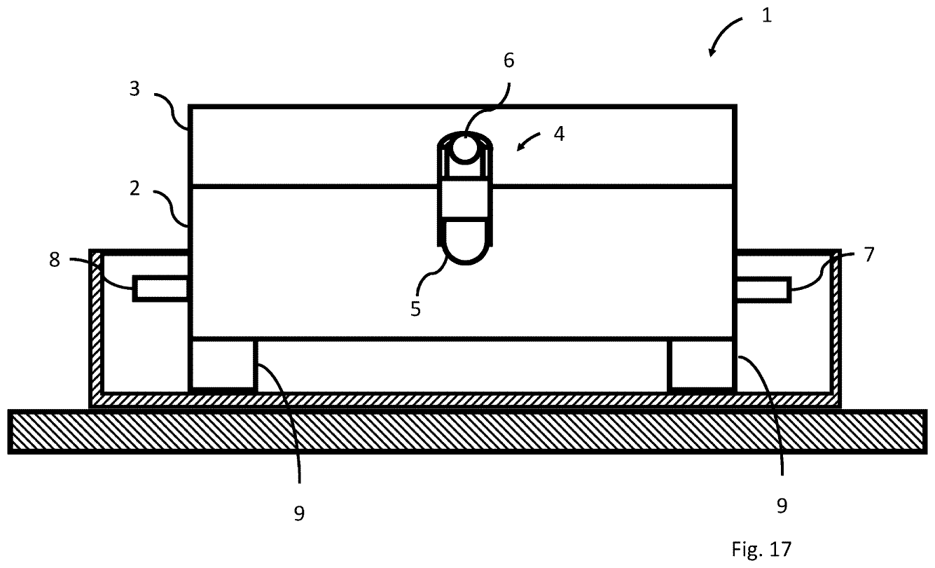

FIG. 16 shows an example of the etching device 1 according to the invention in a side view, in which the etching device 1 is arranged in a drip tray 41, and the drip tray 41 itself is arranged on a base 42. In the example shown, the base 42 is designed as a microscope stage. FIG. 17 shows the etching device 1 of FIG. 16 in a schematic section, in which it can be seen that the etching device is in contact with the drip tray 41 via its already described feet 9.

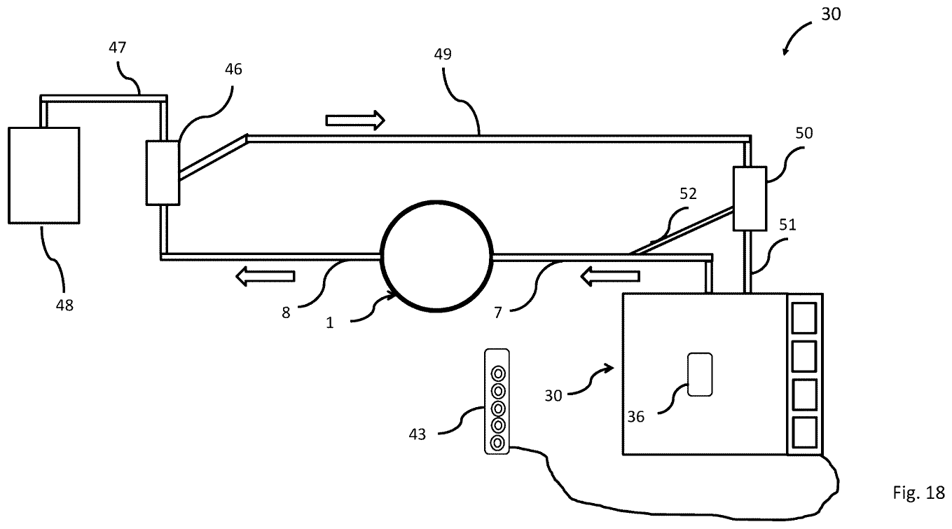

FIG. 18 shows the etching system 30, which has already been partially explained with reference to FIGS. 12 to 15, and is operated with an etching device 1 according to the invention according to FIGS. 1 to 11 in an etchant circuit.

According to FIG. 18, the part of the etching system 30 shown in FIGS. 12 to 15 is connected to the etching liquid supply line 7 via one of the supply lines 40. Via a remote control 43 or the input unit 36, it is possible to set, as already explained, the volume flow, the time or the temperature at which an etching liquid is to be conveyed through the etching liquid supply line 7 into the etching device 1.

After the etching process, the etching liquid exits the etching device 1 again through the etchant discharge line 8 and reaches a first two-way valve 46. This is designed to be electrically controllable and is connected to the control unit 37 for signal transmission. Via an electrical control signal, the etching liquid emerging from the etching device 1 can optionally be guided via a discharge line 47 into an etchant reservoir 48. The etchant reservoir 48 allows an amount of etching liquid contaminated by the etching process to be conducted out of the etching system 30. It is within the scope of the example shown in FIG. 18 that the contaminated etching liquid is conducted out of the etching system 30 as needed and depending on a user input via the remote control 43 or automatically and at regular intervals.

Alternatively, the first two-way valve 46 can be controlled via an electrical control signal such that the etching liquid is conducted into a return line 49. The etching liquid passes via the return line 49 to a second two-way valve 50, which is also designed to be electrically controllable and is connected to the control unit 43 for signal transmission.

The etching liquid in the return line 49 can be returned to one of the etchant sources 31 via the second two-way valve 50 in order to be able to be reused later. Alternatively, the etching liquid can be conducted directly into the etchant supply line 7 via the bypass line 52 without first having to be supplied to an etching liquid source 31. In this case, the etching liquid can circulate via the lines 7, 8 and 49 and, upon suitable actuation of the first two-way valve 46, can finally be conducted into the etchant reservoir 48.

As already explained with reference to FIG. 13, one of the etching liquid sources 31 can contain rinsing agent, e.g. in the form of alcohol, which can be conducted into the etching device 1 via the etching liquid supply line 7 in the manner already described above in order to influence the etching process taking place therein. The rinsing agent can then circulate in the etching system 30 for rinsing purposes via the etching liquid discharge line 8 in a manner also already described via the first two-way valve 46, the return line 49, the second two-way valve 50 and the bypass line 52. After completion of such a rinsing process, the rinsing agent can be discharged into the etchant reservoir 48 or another rinsing agent reservoir, by actuating the first two-way valve 46. In a corresponding manner, the etching device 1 can be cleaned by correspondingly actuating the control unit 37 to allow air to pass from the control unit via the etching liquid supply line 7 into the etching device 1, and conducting it from there via the etching liquid discharge line 8, the first two-way valve 46, the discharge line 47 and finally to the etching liquid reservoir 48, from where the air can pass into the external environment.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An etching device for a workpiece to be processed via an etching liquid, the etching device comprising:
a cavity into which the workpiece is adapted to be introduced; and
at least one lock, the cavity being surrounded at least in some regions by the at least one lock of the etching device for the workpiece, the lock and an end face of the etching device facing the lock partially surrounding a gap for an introduction of the etching liquid,
wherein the end face of the etching device facing the lock is transparent at least in some regions.

2. The etching device according to claim 1, wherein the lock is designed as at least one projection between the cavity and the gap, which is annular.

3. The etching device according to claim 1, wherein at least one clamping element is provided in the cavity such that the workpiece that is introduced into the cavity and/or a workpiece holder that is adapted to be introduced into the cavity and to which the workpiece is attached is clamped with the lock.

4. The etching device according to claim 3, wherein the clamping element has a spring element or a metal spring.

5. The etching device according to claim 1, wherein a workpiece receptacle is arranged in the cavity in order to receive the workpiece to be processed and/or the workpiece holder that is introduced into the cavity and to which the workpiece is attached, and wherein the workpiece receptacle has the clamping element.

6. The etching device according to claim 1, wherein a supply channel for the etching liquid that opens into the gap is designed to widen at least in portions in the direction of the gap.

7. The etching device according to claim 3, wherein the clamping element is electrically conductively connected to an electrical connection.

8. The etching device according to claim 1, wherein a heating element is arranged in the cavity, and wherein the heating element heats the etching liquid introduced into the gap to a user-defined temperature.

9. The etching device according to claim 1, wherein a support surface of the etching device, which is designed as at least one foot, has a pressure sensor.

10. The etching device according to claim 1, wherein the etching device is designed in two parts, wherein a lower part of the etching device comprises at least part of the cavity, and/or an upper part of the etching device comprises the lock and/or the gap.

11. The etching device according to claim 1, wherein an optical sensor is arranged such that the workpiece that is introduced into the cavity is detected by the optical sensor at least partially through the transparent region.

12. An etching system comprising:
the etching device according to claim 1; and
at least one etching liquid source, the etching device being connected to the at least one etching liquid source via at least one etching liquid supply line and connected to at least one etching liquid reservoir via at least one etching liquid discharge line.

13. The etching system according to claim 12, wherein a pump device and/or a valve device are connected to the etching liquid supply line and/or to the etching liquid discharge line.

14. The etching system according to claim 13, wherein the pump device and/or the valve device are connected to a control unit such that the etching liquid is introduced into the etching device with a user-defined process parameter, wherein the process parameter comprises at least one parameter from the following group: composition of the etching liquid, flow rate of the etching liquid, density of the etching liquid, time of supply of the etching liquid into the gap, and/or time of discharge of the etching liquid into the gap.
